(19) United States
(12) Patent Application Publication
(10) Pub. No.: US 2025/0210594 A1
(43) Pub. Date: Jun. 26, 2025

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Soohwan LEE, Suwon-si (KR); Youngkun JEE, Suwon-si (KR)

(21) Appl. No.: 18/955,605

(22) Filed: Nov. 21, 2024

(30) Foreign Application Priority Data
Dec. 21, 2023 (KR) 10-2023-0188509

(51) Int. Cl. H01L 25/065; H01L 23/10; H01L 23/367

(52) U.S. Cl. CPC H01L 25/0657; H01L 23/10; H01L 23/3675; H01L 2225/06524; H01L 2225/06589

(57) ABSTRACT

A semiconductor package includes a buffer die, a plurality of core dies sequentially stacked on the buffer die, a dummy support die attached to an uppermost core die among the plurality of core dies by an adhesive member, and a sealing member on outer side surfaces of the plurality of core dies and an outer side surface of the dummy support die. The dummy support die includes an overhang portion that protrudes from the outer side surface of the uppermost core die. The adhesive member includes a fillet portion that is in contact with the overhang portion and that is on at least a portion of the outer side surface of the uppermost core die.

### PRIORITY STATEMENT

This application claims priority under 35 U.S.C. § 119 to Korean Patent Application No. 10-2023-0188509, filed on Dec. 21, 2023 in the Korean Intellectual Property Office (KIPO), the disclosure of which is incorporated by reference herein in its entirety.

### BACKGROUND

### 1. Field

Example embodiments relate to a semiconductor package and a method of manufacturing the semiconductor package. More particularly, example embodiments relate to a semiconductor package including a plurality of sequentially stacked semiconductor chips and a method of manufacturing the same.

### 2. Description of the Related Art

To manufacture a multi-chip package in which at least four semiconductor chips are stacked, as the number of the stacked chips increases, an amount of deformation of the chips may accumulate, so that the chips in relatively high levels may have curved surfaces. When a relatively thick uppermost core die is bonded to an underlying core die, it may be difficult to deform the uppermost core die, so voids generated at the bonding interface may not be discharged, deteriorating the quality of the interfacial bonding in hybrid bonding.

### SUMMARY

Example embodiments provide a semiconductor package having improved bonding quality and improved heat dissipation performance.

Example embodiments provide a method of manufacturing the semiconductor package.

According to example embodiments, a semiconductor package includes a buffer die, a plurality of core dies sequentially stacked on the buffer die, a dummy support die attached to an uppermost core die among the plurality of core dies by an adhesive member, and a sealing member on outer side surfaces of the plurality of core dies and an outer side surface of the dummy support die. The dummy support die includes an overhang portion that protrudes from the outer side surface of the uppermost core die. The adhesive member includes a fillet portion in contact with the overhang portion and that is on at least a portion of the outer side surface of the uppermost core die.

According to example embodiments, a semiconductor package includes a buffer die; a plurality of core dies sequentially stacked on the buffer die, each of the plurality of core dies having a first width; a dummy support die on an uppermost core die among the plurality of core dies, the dummy support die having a second width that is greater than the first width; an adhesive member interposed between the uppermost core die and the dummy support die; and a sealing member on outer side surfaces of the plurality of core dies and an outer side surface of the dummy support die. The adhesive member includes a fillet portion on at least a portion of an outer side surface of the uppermost core die.

According to example embodiments, a semiconductor package includes a buffer die, a plurality of core dies sequentially stacked on the buffer die, a dummy support die attached to an uppermost core die among the plurality of core dies by an adhesive member, and a sealing member on outer side surfaces of the plurality of core dies and an outer side surface of the dummy support die. Each of the plurality of core dies has a first thickness, and the dummy support die has a second thickness greater than the first thickness. Each of the plurality of core dies has a first width, and the dummy support die has a second width greater than the first width. The adhesive member includes a fillet portion on at least a portion of the outer side surface of the uppermost core die.

According to example embodiments, a semiconductor package may include a plurality of core dies sequentially stacked on a buffer die, a dummy support die attached on an uppermost core die of the plurality of core dies by an adhesive member, and a sealing member on the buffer die and covering the plurality of core dies and an outer side surface of the dummy support die. The dummy support die may include an overhang portion that protrudes from an outer side surface of the uppermost core die, and the adhesive member may include a fillet portion in contact with the overhang portion that is on at least a portion of the outer side surface of the uppermost core die.

The uppermost core die may have a curved surface due to an accumulated amount of deformation occurring in the stacked core dies. By attaching the relatively thick dummy support die using the adhesive member on the curved surface of the uppermost core die, delamination or bubbles may be prevented from occurring at the bonding interface of the uppermost core die, to thereby improve the bonding quality. Further, since the dummy support die has excellent thermal conductivity, the heat dissipation characteristics of the package may be improved.

### BRIEF DESCRIPTION OF THE DRAWINGS

Example embodiments will be more clearly understood from the following detailed description taken in conjunction with the accompanying drawings. FIGS. 1 to 21 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is an enlarged cross-sectional view illustrating portion ‘B’ in FIG. 1.

FIG. 4 is an enlarged cross-sectional view illustrating portion ‘C’ in FIG. 1.

FIGS. 5 to 19 are views illustrating a method of manufacturing a semiconductor package in accordance with example embodiments.

FIG. 20 is a cross-sectional view illustrating a semiconductor package in accordance with example embodiments.

FIG. 21 is an enlarged cross-sectional view illustrating portion ‘I’ in FIG. 20.

### DETAILED DESCRIPTION OF EXAMPLE EMBODIMENTS

Hereinafter, example embodiments will be explained in detail with reference to the accompanying drawings.

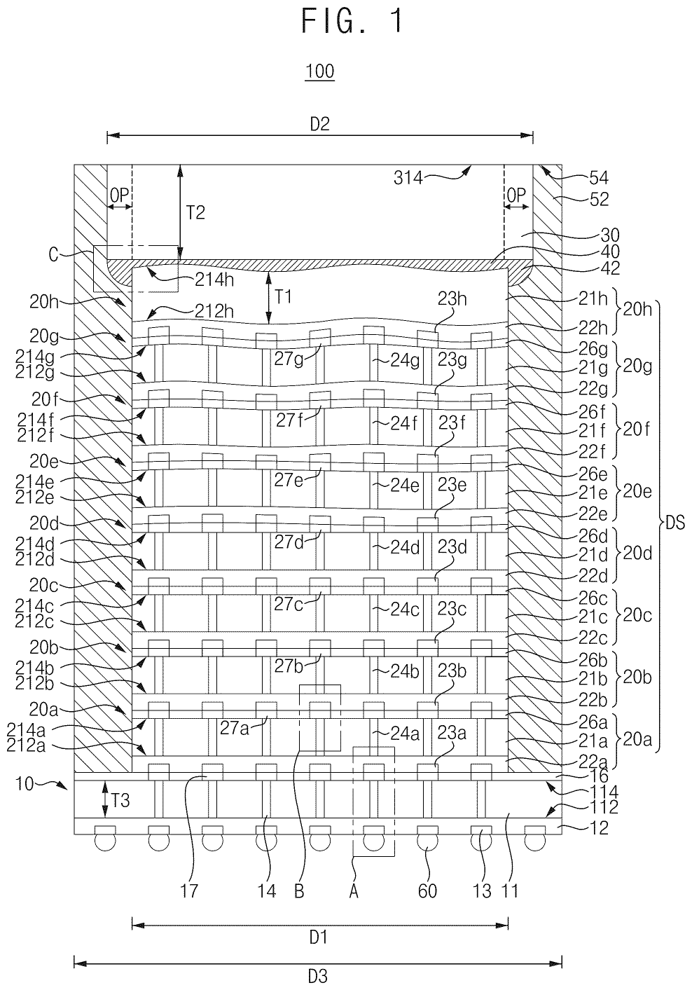

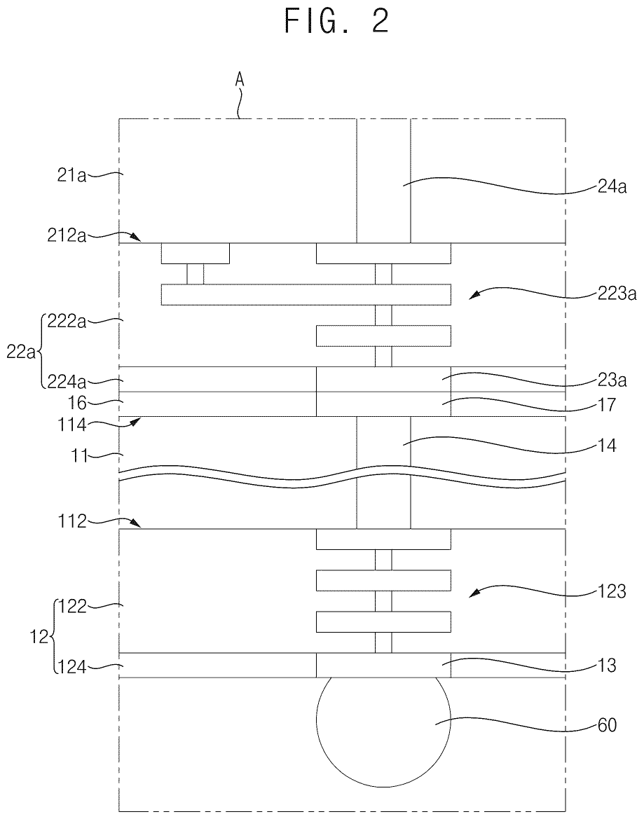

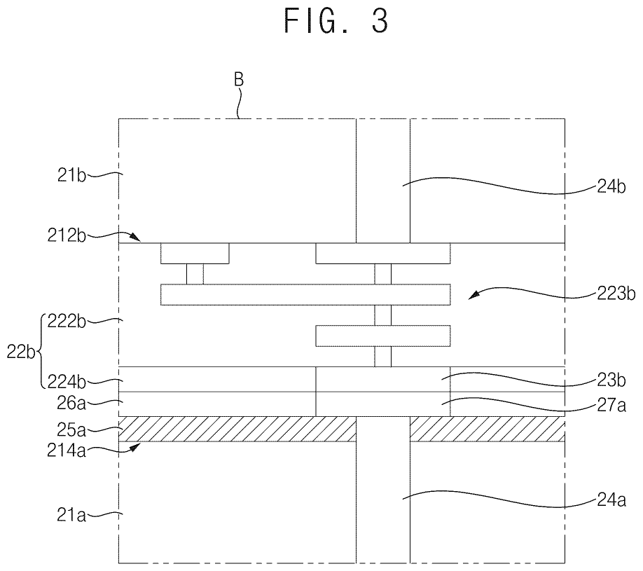

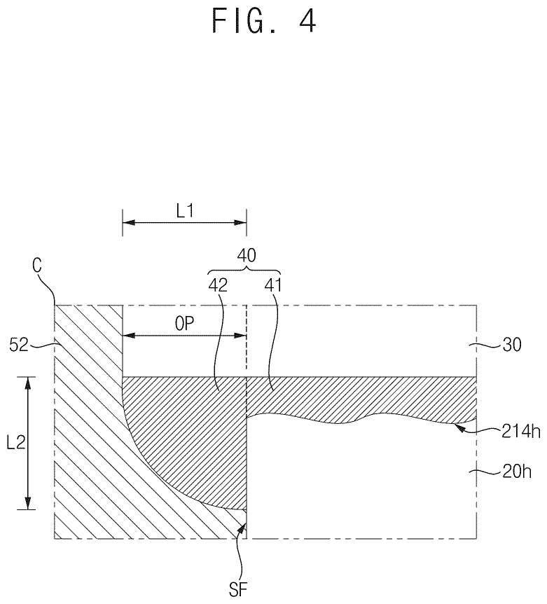

FIG. 1 is a cross-sectional view illustrating a semiconductor package in accordance with example embodiments. FIG. 2 is an enlarged cross-sectional view illustrating portion ‘A’ in FIG. 1. FIG. 3 is an enlarged cross-sectional view illustrating portion ‘B’ in FIG. 1. FIG. 4 is an enlarged cross-sectional view illustrating portion ‘C’ in FIG. 1.

Referring to FIGS. 1 to 4, a semiconductor package 100 may include semiconductor chips (dies) 20 stacked therein. The semiconductor package 100 may include a buffer die 10, a core die stack DS, a dummy support die 30, an adhesive member 40, and a sealing member 52.

The core die stack DS may include a plurality of semiconductor chips (dies) 20a, 20b, 20c, 20d, 20e, 20f, 20g and 20h that are stacked vertically. In this embodiment, the semiconductor chips (dies) 20a, 20b, 20c, 20d, 20e, 20f, 20g and 20h may be substantially the same as or similar to each other. Accordingly, same or like reference numerals will be used to refer to the same or like elements and repeated descriptions of the same elements may be omitted.

In this embodiment, the semiconductor package as a multi-chip package is illustrated as including eight stacked semiconductor chips 20a, 20b, 20c, 20d, 20e, 20f, 20g and 20h on the buffer die 10, however, it may not limited thereto. For example, the semiconductor package may include 12, 16, or 20 stacked semiconductor chips.

Each of the semiconductor chips 20a, 20b, 20c, 20d, 20e, 20f, 20g and 20h may include an integrated circuit chip completed by performing semiconductor manufacturing processes. Each semiconductor chip may include, for example, a memory chip or a logic chip. The semiconductor package 100 may include a memory device. The memory device may include a high bandwidth memory (HBM) device.

In example embodiments, a buffer die 10 may include a substrate 11, a front insulating layer 12, a plurality of first bonding pads 13, a plurality of through electrodes 14, and a backside insulating layer 16, and a plurality of second bonding pads 17. Additionally, the buffer die 10 may further include conductive bumps 60 as conductive connection members respectively provided on the first bonding pads 13. The buffer die 10 may be mounted on a package substrate or an interposer via the conductive bumps 60. For example, the conductive bump 60 may include a solder bump. Alternatively, the conductive bump 60 may include a pillar bump and a solder bump formed on the pillar bump.

The substrate 11 may have a first surface 112 and a second surface 114 opposite to the first surface 112. The first surface 112 may be an active surface, and the second surface 114 may be a non-active surface. Circuit patterns may be provided on the first surface 112 of the substrate 11. The first surface 112 may be referred to as a front surface on which the circuit patterns are formed, and the second surface may be referred to as a backside surface.

For example, the substrate 11 may be a single crystal silicon substrate. The circuit patterns may include transistors, capacitors, diodes, etc. The circuit patterns may constitute circuit elements. Accordingly, the buffer die 10 may be a semiconductor device having a plurality of circuit elements formed therein.

As illustrated in FIG. 2, the front insulating layer 12 as an insulation interlayer may be formed on the first surface 112 of the substrate 11, that is, the front surface. The front insulating layer 12 may include a plurality of insulating layers 122 and 124 and wirings 123 in the insulating layers. Additionally, the first bonding pad 13 may be provided in an outermost insulating layer of the front insulating layer 12.

For example, the front insulating layer 12 may include a metal wiring layer 122 and a first passivation layer 124. The metal wiring layer 122 may include a plurality of wirings 123 therein. For example, the metal wiring layer 122 may include a metal interconnection structure including a plurality of wirings 123 vertically stacked in buffer layers and insulating layers. The first bonding pad 13 may be formed on an uppermost wiring among the plurality of wirings 123. For example, the wirings may include aluminum (Al), copper (Cu), tin (Sn), nickel (Ni), gold (Au), platinum (Pt), or alloys thereof.

The first passivation layer 124 may be formed on the metal wiring layer 122 and may expose at least a portion of the first bonding pad 13. The first passivation layer 124 may include a plurality of stacked insulating layers. For example, the first passivation layer 224 may include a first protective layer including an oxide layer and a second protective layer including a nitride layer, sequentially stacked. The first protective layer may include silicon oxide, and the second protective layer may include silicon nitride or silicon carbonitride.

The first bonding pad 13 may be provided in the first passivation layer 124. The first bonding pad 13 may be exposed through (i.e., exposed at) an outer surface of the first passivation layer 124. Although not illustrated in the figures, an insulation interlayer may be provided on the first surface 112 of the substrate 11 to cover the circuit patterns. The insulation interlayer may be formed to include, for example, silicon oxide or a low dielectric material. The insulation interlayer may include lower wiring therein, which are electrically connected to the circuit patterns. Accordingly, the circuit pattern may be electrically connected to the first bonding pad 13 by the lower wirings and the wirings.

The through electrode (through silicon via, TSV) 14 may vertically penetrate the insulation interlayer and extend from the first surface 112 to the second surface 114 of the substrate 11. The through electrode 14 may contact a lowermost wiring of the metal wiring structure. Accordingly, the through electrode 24 may be electrically connected to the first bonding pad 13 by the wirings 123.

The backside insulating layer 16 may be formed on the second surface 114 of the substrate 11, that is, the backside surface. The second bonding pad 17 may be provided in the backside insulating layer 16. For example, the second bonding pad 17 may be disposed on an exposed surface of the through electrode 14. The backside insulating layer 16 may include silicon oxide, carbon-doped silicon oxide, silicon carbonitride (SiCN), etc. Accordingly, the first and second bonding pads 13 and 17 may be electrically connected to each other by the through electrode 24

In example embodiments, the core die stack DS may include a plurality of core dies 20a, 20b, 20c, 20d, 20e, 20f, 20g and 20h that are stacked vertically on the buffer die 10. In this embodiment, the core die stack DS includes eight stacked core dies, however, it may not be limited thereto. For example, the core die stack DS may include 12, 16, or 20 stacked core dies.

Each of the core dies may include a substrate 21, a front insulating layer 22 provided on a front surface of the substrate 21 and in which a first bonding pad 23 is provided, and a backside insulating layer 26 provided on a backside surface of the substrate 21 and in which a second bonding pad 27 is provided. In addition, each of the core dies may further include a through electrode 24 that penetrates the substrate 21 and is electrically connected to the first and second bonding pads 23 and 27.

As illustrated in FIGS. 2 and 3, a first-stage core die 20a of the core die stack DS may include a substrate 21a, a front insulating layer 22a, a plurality of first bonding pads 23a, a plurality of through electrodes 24a, a backside insulating layer 26a and a plurality of second bonding pads 27a.

The substrate 21a may have a first surface 212a and a second surface 214a opposite to the first surface 212a. The first surface 212a may be an active surface, and the second surface 214a may be a non-active side. Circuit patterns may be provided on the first surface 212a of the substrate 21a. The front insulating layer 22a as an insulation interlayer may be formed on the first surface 212a of the substrate 21a, that is, a front surface. The front insulating layer 22a may include a plurality of insulating layers 222a and 224a and wirings 223a in the insulating layers 222a and 224a. Additionally, the first bonding pad 23a may be provided in an outermost insulating layer of the front insulating layer 22a. For example, the front insulating layer 22a may include a metal wiring layer 222a and a first passivation layer 224a. The metal wiring layer 222a may include a plurality of wirings 223a therein.

The through electrode 24a may penetrate the insulation interlayer and vertically extend from the first surface 212a to the second surface 214a of the substrate 21a. The through electrode 24a may be electrically connected to the first bonding pad 23a by the wirings 223a. The backside insulating layer 26a may be formed on the second surface 214a of the substrate 21a, that is, a backside surface. The second bonding pad 27a may be provided in the backside insulating layer 26a. Accordingly, the first and second bonding pads 23a and 27a may be electrically connected to each other by the through electrode 24a.

Similarly, a second-stage core die 20b of the core die stack DS may include a substrate 21b, a front insulating layer 22b, a plurality of first bonding pads 23b, a plurality of through electrodes 24b, a backside insulating layer 26b, and a plurality of second bonding pads 27b. Since the core dies 20a, 20b, 20c, 20d, 20e, 20f, 20g and 20h are substantially the same as or similar to each other, same or like reference numerals will be used to refer to the same or like elements and repeated descriptions of the same elements may be omitted.

As illustrated in FIG. 2, the first-stage core die (first core die) 20a and the buffer die 10 may be bonded to each other by hybrid bonding. The second bonding pad 17 of the buffer die 10 and the first bonding pad 23a of the first core die 20a may be bonded to each other by copper-copper hybrid bonding (Cu—Cu Hybrid Bonding). The front surface of the first core die 20a, that is, the front insulating layer 23a on the first surface 212a of the substrate 21a may be directly bonded to the backside insulating layer 16 of the substrate 11 of the buffer die 10.

As illustrated in FIG. 3, the second-stage core die (second core die) 20b and the first-stage core die 20a may be bonded to each other by hybrid bonding. The second bonding pad 27a of the first-stage core die 20a and the first bonding pad 23b of the second-stage core die 20b may be bonded to each other by copper-copper hybrid bonding (Cu—Cu Hybrid Bonding).

The front insulating layer 22b on the front surface of the second-stage core die 20b may be directly bonded to the backside insulating layer 26a on the backside surface of the first-stage core die 20a. The outermost insulating layers of the backside insulating layer 26a and the front insulating layer 22b may include an insulating material that contacts each other and provides excellent bonding strength, thereby providing a bonding structure. The backside insulating layer 26a and the front insulating layer 22b may be bonded to each other by a high temperature annealing process while in contact with each other. Here, the bonding structure may have a relatively stronger bonding strength by covalent bonding.

Similarly, third to eighth-stage core dies 20c, 20d, 20e, 20f, 20g, and 20h may be bonded to each other by hybrid bonding.

Among the core dies of the core die stack DS, the uppermost core die 20h may include a substrate 21h and a front insulating layer 22h provided on a front surface of the substrate 21h and in which a first bonding pad 23h is provided. Unlike the other core dies 20a, . . . , 20g, a back insulating layer may not be provided on a second surface 214h, that is, an inactive surface, of the substrate 21h of the uppermost core die 20h. Additionally, the substrate 21h of the uppermost core die 20h may not be provided with through electrodes.

The uppermost core die 20h may have a thickness the same as those of the underlying core dies 20a, . . . , 20g. As the number of the stacked core dies increases, a cumulative amount of deformation occurring in the core dies increases, so that the backside surface 214h of the uppermost core die 20h has a curved surface shape.

The core dies of the core die stack DS may have same first thicknesses T1. The first thickness T1 of each of the core dies may be within a range of about 20 μm to 100 μm. The core dies of the core die stack DS may have same first widths W1. The first width W1 of each of the core dies may be within a range of 3 mm to 30 mm.

In example embodiments, the dummy support die 30 may be attached to the uppermost core die 20h of the core die stack DS by the adhesive member 40. A thermal conductivity of the dummy support die 30 may be greater than a thermal conductivity of each of the core dies. The dummy support die 30 may have a second thickness T2 greater than the first thickness T1 of the core die. The second thickness T2 of the dummy support die 30 may be within a range of 50 μm to 780 μm. The dummy support die 30 may have a second width D2 that is greater than the first width D1 of the core die. The dummy support die 30 may include an overhang portion OP protruding from an outer side surface of the uppermost core die 20h. A length L1 (FIG. 4) of the overhang portion OP protruding from the outer side surface SF of the uppermost core die 20h may be within a range of 30 μm to 300 μm. The adhesive member 40 may include a non-conductive film (NCF). Alternatively, the adhesive member 40 may include epoxy, silicone, etc. A thickness of the adhesive member 40 may be within a range of 10 μm to 30 μm.

For example, since the dummy support die 30 is attached by a thermal compression process, a portion of the adhesive member 40 between the uppermost core die 20h and the dummy support die 30 may be dispersed in an outward direction. Accordingly, the portion of the adhesive member 40 may extend downward from the overhang portion OP of the dummy support die 30 and may form a fillet portion 42 that covers at least a portion of the outer side surface SF of the uppermost core die 20h.

As illustrated in FIG. 4, the adhesive member 40 may include an adhesive portion 41 between the dummy support die 30 and the uppermost core die 20h and the fillet portion 42 that extends downward from a periphery of the adhesive portion 41 to cover the at least a portion of the outer side surface SF of the uppermost core die 20h. The fillet portion 42 may extend downward from a lower surface of the overhang portion OP of the dummy support die 30 by a second length L2. The second length L2 may be within a range of 10 μm to 80 μm.

In example embodiments, the sealing member 52 may be provided on the buffer die 10 to cover an outer side surface of the core die stack DS and an outer side surface of the dummy support die 30. The sealing member 52 may expose an upper surface 314 of the dummy support die 30, as illustrated in FIG. 1. An upper surface 54 of the sealing member 52 may be coplanar with the upper surface 314 of the dummy support die 30.

For example, the sealing member 52 may include epoxy molding compound (EMC), an inorganic dielectric layer, an organic dielectric layer, etc. The inorganic dielectric layer may include silicon oxide, silicon oxynitride, phosphosilicate glass (PSG), boro-phosphosilicate glass (BPSG), etc. The organic dielectric layer may include a polymer or the like.

In example embodiments, a third width D3 of the buffer die 10 may be greater than the first width D1 of the core die stack DS. Alternatively, third width D3 of the buffer die 10 may be the same as the first width D1 of the core die stack DS

As mentioned above, the semiconductor package 100 may include the core die stack DS stacked on the buffer die 10, the dummy support die 30 attached on the uppermost core die 20h of the core die stack DS by the adhesive member 40, and the sealing member 52 on the buffer die 10 and covering the core die stack DS and the dummy support die 30. The dummy support die 30 may include the overhang portion OP protruding from the outer side surface SF of the uppermost core die 20h, and the adhesive member 40 may include the fillet portion 42 that extends downward from the overhang portion OP to cover the at least a portion of the outer side surface SF of the uppermost core die 20h.

Since the uppermost core die 20h has the thickness the same as or similar to those of the other core dies 20a, . . . , 20g under the uppermost core die 20, the backside surface 214h of the uppermost core die 20h may have a curved surface depending on the accumulated amount of deformation occurring in the stacked core dies. By attaching the relatively thick dummy support die 30 using the adhesive member 40 on the curved surface of the uppermost core die, delamination or bubbles may be prevented from occurring at the bonding interface of the uppermost core die 20h, to thereby improve the bonding quality.

Further, in a molding process to form the sealing member 52, a portion of the adhesive member 40 distributed and dispersed outside the uppermost core die 20h may be blocked by the overhang portion OP, and accordingly, a failure that the dispersed portion of the adhesive member 40 moves upward to protrude outward from the upper surface 54 of the sealing member 52 may be prevented. Moreover, since the dummy support die 30 has excellent thermal conductivity, the heat dissipation characteristics of the package may be improved.

Hereinafter, a method of manufacturing the semiconductor package of FIG. 1 will be described. A case where the semiconductor package includes a high bandwidth memory (HBM) device will be described. However, it will be understood that a method of manufacturing a semiconductor package in accordance with example embodiments is not limited thereto.

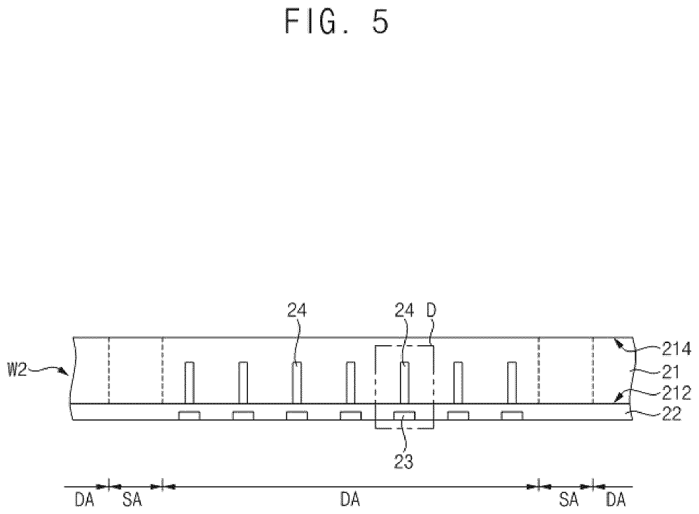

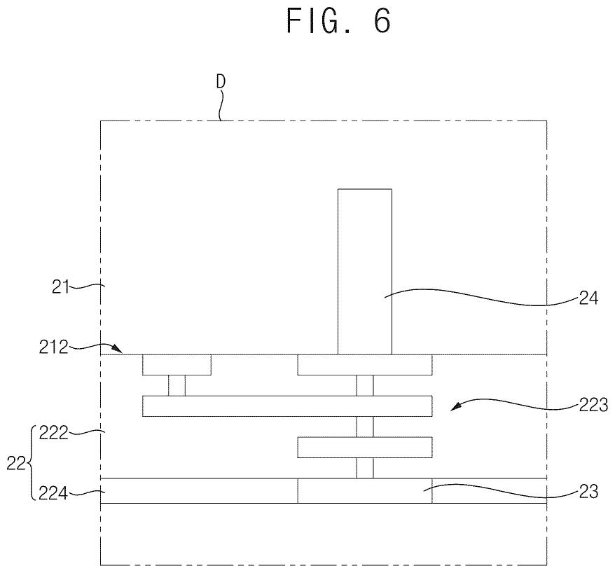

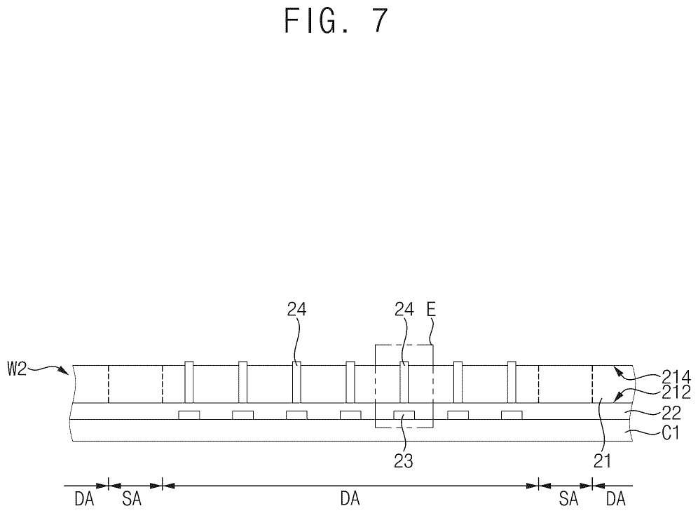

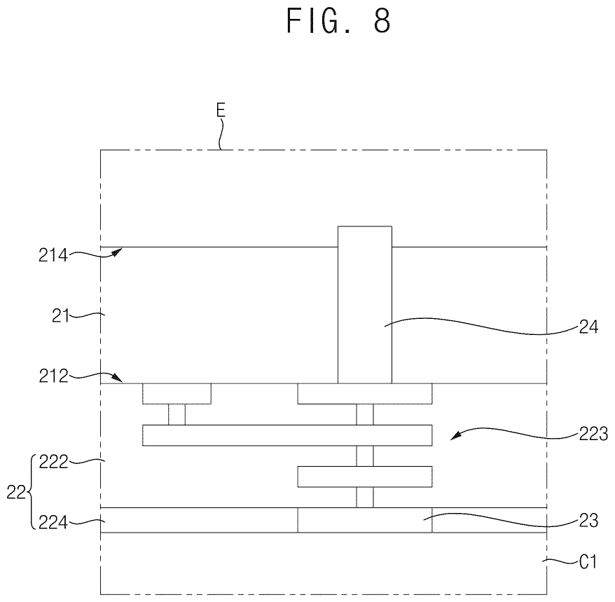

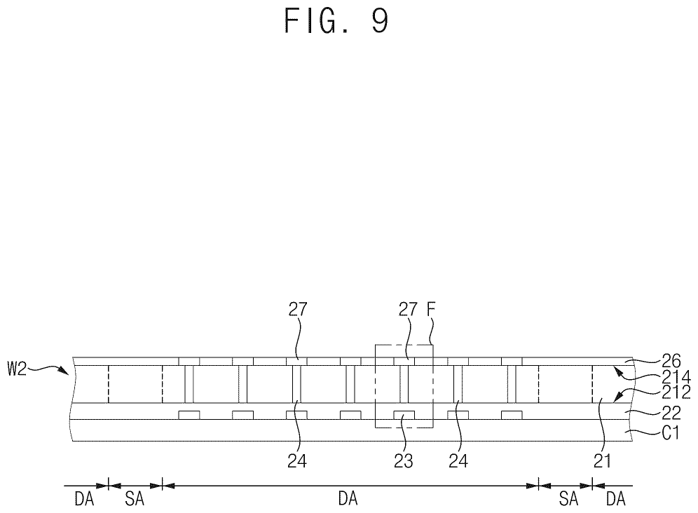

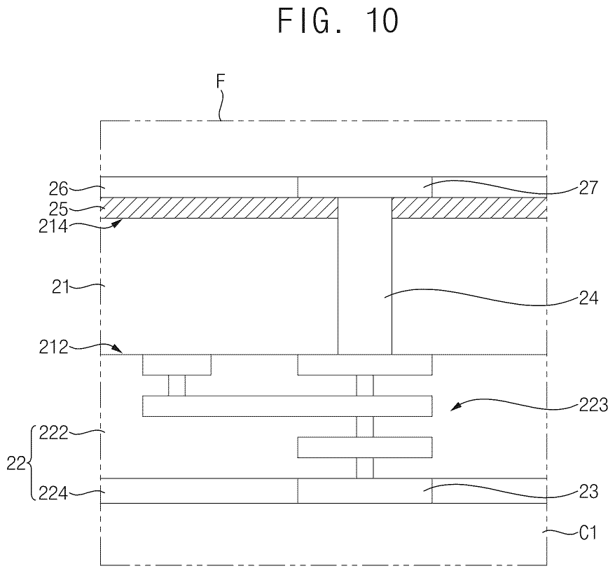

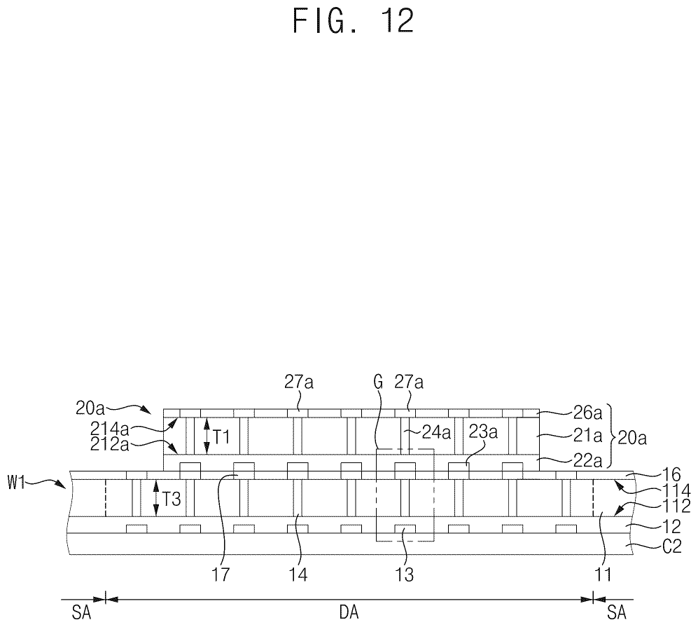

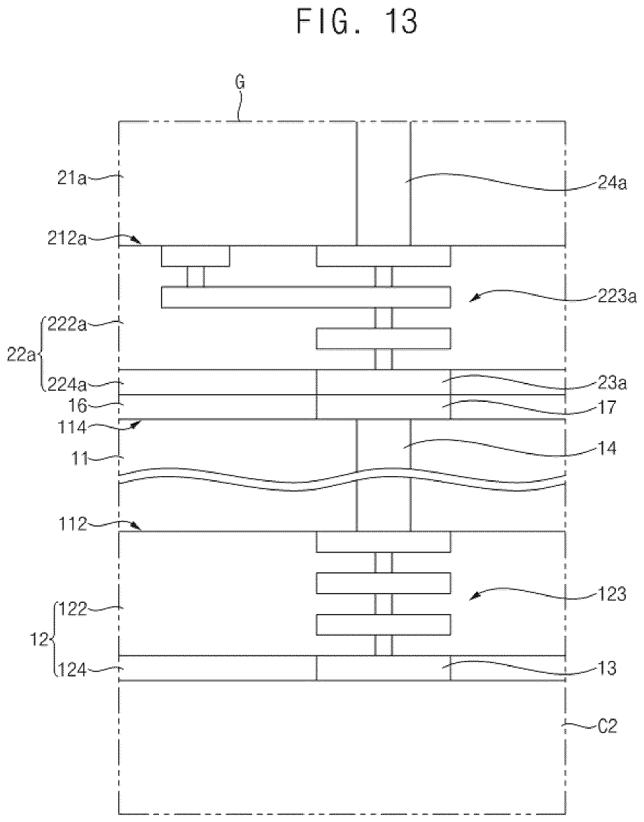

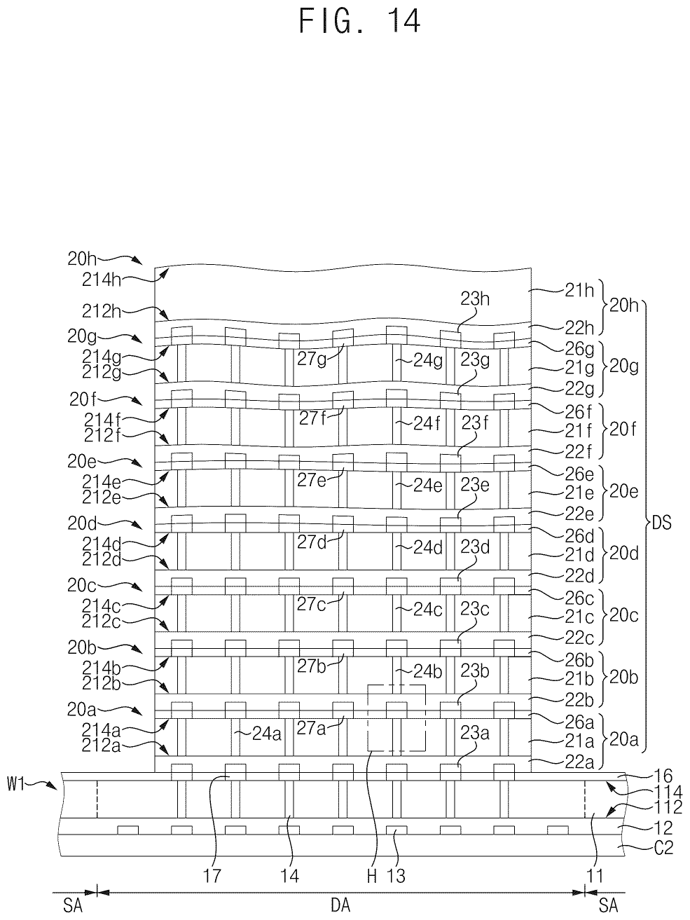

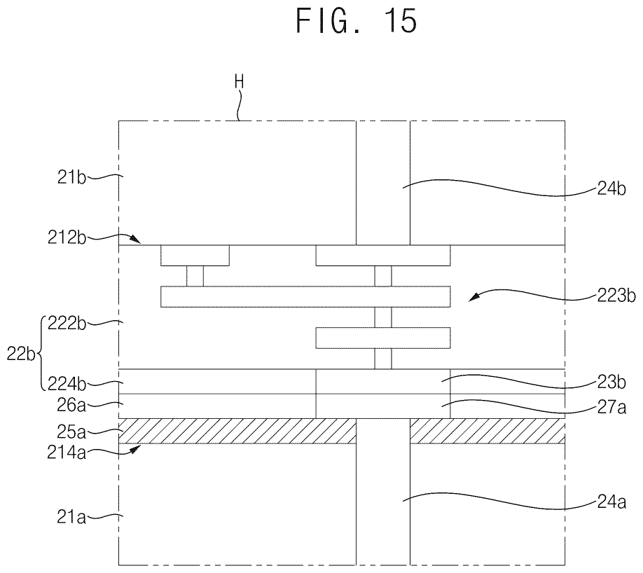

FIGS. 5 to 19 are views illustrating a method of manufacturing a semiconductor package in accordance with example embodiments. FIG. 6 is an enlarged cross-sectional view illustrating portion ‘D’ in FIG. 5. FIG. 8 is an enlarged cross-sectional view illustrating portion ‘E’ in FIG. 7. FIG. 10 is an enlarged cross-sectional view illustrating portion ‘F’ in FIG. 9. FIG. 13 is an enlarged cross-sectional view illustrating portion ‘G’ in FIG. 12. FIG. 15 is an enlarged cross-sectional view illustrating portion ‘H’ in FIG. 14.

Referring to FIGS. 5 to 11, first, a second wafer W2 may be individualized into semiconductor chips (core dies) 20.

As illustrated in FIGS. 5 and 6, the second wafer W2 including a plurality of semiconductor chips (core dies) formed therein may be prepared.

In example embodiments, the second wafer W2 may include a substrate 21 and a front insulating layer 22 having a first bonding pad 23 that is provided in an outer surface thereof. Additionally, the second wafer W2 may include a plurality of through electrodes 24 that are provided in the substrate 21 and are electrically connected to the first bonding pads 23.

The substrate 21 may have a first surface 212 and a second surface 214 opposite to each other. The substrate 21 may include a die region DA where circuit patterns and cells are formed and a scribe lane region SA surrounding the die region DA. The substrate 21 may be cut along the scribe lane region SA that divides the plurality of die regions DA of the second wafer W2 by a following deicing process to form individualized semiconductor chips.

For example, the substrate 21 may include silicon, germanium, silicon-germanium, or III-V compounds, e.g., GaP, GaAs, GaSb, etc. In some embodiments, the substrate 21 may be a silicon-on-insulator (SOI) substrate, or a germanium-on-insulator (GOI) substrate.

The circuit patterns may include transistors, capacitors, diodes, etc. The circuit patterns may constitute circuit elements. Accordingly, the semiconductor chip may be a semiconductor device with a plurality of the circuit elements formed therein. The circuit patterns may be formed on the first surface 212 of the substrate 21 by performing a FEOL (Front End of Line) process for manufacturing semiconductor devices. The surface of the substrate on which the FEOL process is performed may be referred to as a front surface of the substrate, and a surface opposite to the front surface may be referred to as a backside surface.

The circuit element may include a plurality of memory devices. Examples of the memory devices include a volatile semiconductor memory device and a non-volatile semiconductor memory device. Examples of the volatile semiconductor memory device may be DRAM, SRAM, etc. Examples of the non-volatile semiconductor memory devices may be EPROM, EEPROM, Flash EEPROM, etc.

The front insulating layer 22 may be formed as an insulation interlayer on the first surface 212 of the substrate 21, that is, the front surface. The front insulating layer 22 may include a plurality of insulating layers 222 and 224 and wirings 223 in the insulating layers. Additionally, the first bonding pad 23 may be provided in the outermost insulating layer of the front insulating layer 22.

As illustrated in FIG. 6, for example, the front insulating layer 22 may include a metal wiring layer 222 and a first passivation layer 224.

The metal wiring layer 222 may include the plurality of wirings 223 therein. For example, the metal wiring layer 222 may include a metal wiring structure including the plurality of wirings 223 vertically stacked in buffer layers and insulating layers. The first bonding pad 23 may be formed on an uppermost wiring among the plurality of wirings 223. For example, the wirings may include aluminum (Al), copper (Cu), tin (Sn), nickel (Ni), gold (Au), platinum (Pt), or alloys thereof.

The first passivation layer 224 may be formed on the metal wiring layer 222 and may expose at least a portion of the first bonding pad 23. The first passivation layer 224 may include a plurality of stacked insulating layers. For example, the first passivation layer 224 may include a first protective layer including an oxide layer and a second protective layer including a nitride layer, sequentially stacked. The first protective layer may include silicon oxide, and the second protective layer may include silicon nitride or silicon carbonitride.

The first bonding pad 23 may be provided in the first passivation layer 224. The first bonding pad 23 may be exposed from (i.e., exposed at) an outer surface of the first passivation layer 224. Although not illustrated in the figures, an insulation interlayer may be provided on the first surface 212 of the substrate 21 to cover the circuit patterns. The insulation interlayer may be formed to include, for example, silicon oxide or a low dielectric material. The insulation interlayer may include lower wirings therein, which are electrically connected to the circuit patterns. Accordingly, the circuit pattern may be electrically connected to the first bonding pad 23 by the lower wirings and the wirings.

The through electrode (through silicon via, TSV) 24 may vertically penetrate the insulation interlayer and extend from the first surface 212 of the substrate 21 to a predetermined depth. The through electrode 24 may contact a lowermost wiring of the metal wiring structure. Accordingly, the through electrode 24 may be electrically connected to the first bonding pad 23 by the wirings 223.

A liner layer (not illustrated) may be provided on an outer surface of the through electrode 24. The liner layer may include silicon oxide or carbon-doped silicon oxide. The liner layer may electrically insulate the through electrode 24 from the substrate 21 and the metal wiring layer 222.

The through electrode 24 and the first bonding pad 23 may include a same metal. For example, the metal may include copper (Cu). However, it is not limited thereto, and the through electrode and the first bonding pad may include a material (e.g., gold (Au)) that can be bonded by inter-diffusion of metals by a high-temperature annealing process.

As illustrated in FIGS. 7 and 8, the second surface 214 of the substrate 21 may be partially removed to expose one end portion of the through electrode 24.

In example embodiments, the second surface 214 of the substrate 21 may be partially removed using a substrate support system (WSS). For example, the second wafer W2 may be attached to a carrier substrate C1 using an adhesive film, and then, the second surface 214 of the substrate 21 may be partially removed until the end portion of the through electrode 24 is exposed.

In particular, a grinding process such as a back lap process may be performed to partially remove the second surface 214 of the substrate 21, and then an etching process such as a silicon recess process may be performed to expose the end portion of the through electrode 24. Accordingly, a thickness of the substrate 21 may be reduced to a desired thickness. For example, the substrate 21 may have the thickness in a range of about 20 μm to about 100 μm.

In the back lap process, the entire backside surface of the second wafer W2 may be grinded. In the silicon recess process, only the silicon in the backside surface of the second wafer W2 may be selectively etched. The etching process may be an isotropic dry etching process. The etching process may include a plasma etching process, etc. The plasma etching process may be performed using inductively coupled plasma, capacitively coupled plasma, microwave plasma, etc.

Since the grinding process and the etching process are performed in the wafer level, the entire second surface 214 of the substrate 21 may be reduced to a uniform thickness. Accordingly, the end portions of the through electrodes 24 may protrude uniformly from the second surface 214 of the substrate 21 across the entire second surface 214 of the substrate 21 to have same heights.

As illustrated in FIGS. 9 and 10, a backside insulating layer 26 having a second bonding pad 27 in an outer surface thereof may be formed on the second surface 214 of the substrate 21.

For example, an etch stop layer may be formed on the second surface 214 of the substrate 21, and a sacrificial layer may be formed on the etch stop layer. The etch stop layer may be conformally formed to cover the end portions of the through electrodes 24 that protrude from the second surface 214 of the substrate 21. The etch stop layer may cover the entire second surface 214 of the substrate 21. For example, the etch stop layer may have a thickness within a range of 0.1 μm to 1 μm. The etch stop layer may include a material that can be used to detect a polishing end point in a subsequent chemical mechanical polishing process. The etch stop layer may include a silicon nitride layer. The thickness and material of the etch stop layer may be selected in consideration of a polishing selectivity and polishing conditions in the subsequent chemical mechanical polishing process.

The sacrificial layer may be formed on the etch stop layer to fill a gap between the protruding end portions of the through electrodes 24. The sacrificial layer may include silicon oxide such as TEOS.

Then, a chemical mechanical polishing (CMP) process may be performed to remove the sacrificial layer to expose the end portions of the through electrodes 24. In the chemical mechanical polishing (CMP) process, the etch stop layer may be used to detect a polishing end point. Through the CMP process, the end portions of the through electrodes 24 and portions of the etch stop layer covering the end portions of the through electrodes 24 may be removed to form an etch stop layer pattern 25 on the second surface 214 of the substrate 21.

The etch stop layer pattern 25 may expose the end portions of the through electrodes 24. The end portions of the through electrodes 24 may protrude from the second surface 214 of the substrate 21, and the etch stop layer pattern 25 may cover sidewalls of the end portions of the through electrodes that protrude from the second surface 214 of the substrate 210. Accordingly, upper surfaces of the through electrodes 24 may be exposed by the etch stop layer pattern 25. An upper surface of the etch stop layer pattern 25 and the exposed upper surfaces of the through electrodes 24 may be positioned on the same plane.

Then, the backside insulating layer 26 as a second passivation layer may be formed on the etch stop layer pattern 25 on the second surface 214 of the substrate 21. The backside insulating layer 26 may have the second bonding pad 27 that is electrically connected to the through electrode 24.

For example, after the backside insulating layer 26 is formed on the etch stop layer pattern 25 on the second surface 214 of the substrate 21, an opening may be formed in the backside insulating layer 26 to expose the through electrode 24, and a plating process may be performed to form the second bonding pad 27 in the opening of the backside insulating layer 26. The second bonding pad 27 may be disposed on the exposed surface of the through electrode 24. The backside insulating layer 26 may include silicon oxide, carbon-doped silicon oxide, silicon carbonitride (SiCN), etc. Accordingly, the first and second bonding pads 23 and 27 may be electrically connected to each other by the through electrode 24.

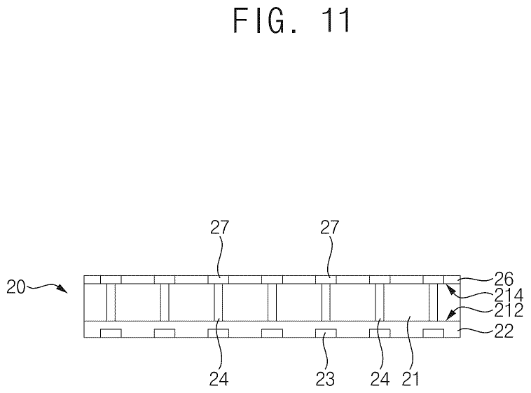

Referring to FIG. 11, the second wafer W2 may be cut along the scribe lane region SA to form individual second semiconductor chips (core dies) 20. The individual second semiconductor chip 20 may be separated from the carrier substrate C1.

Referring to FIGS. 12 to 15, a core die stack DS including a plurality of core dies 20a, 20b, 20c, 20d, 20e, 20f, 20g and 20h may be formed on a first wafer W1. In this embodiment, the core die stack DS includes eight stacked core dies 20a, 20b, 20c, 20d, 20e, 20f, 20g and 20h, however, it may not limited thereto.

As illustrated in FIGS. 12 and 13, a plurality of first core dies 20a may be attached in a first stage on the first wafer W1 (die-to-wafer hybrid bonding process).

In example embodiments, the first core dies 20a may be disposed on the first wafer W1 to correspond to die regions DA. The first core dies 20a may be stacked such that a first surface 212a of a substrate 21a faces the first wafer W1.

A die bonding apparatus may pick up the first core die 20a individualized through a sawing process and may bond it to the first wafer W1. The die bonding apparatus may attach the first core die 20a to the first wafer W1 by performing a thermal compression process at a predetermined temperature (for example, about 400° C. or less). By the thermal compression process, the first core die 20a and the first wafer W1 may be bonded to each other through hybrid bonding. That is, a front surface of the first core die 20a, that is, a front insulating layer 23a on the first surface 212a of the substrate 21a may be directly bonded to a backside insulating layer 16 on a substrate 11 of the first wafer W1.

A second bonding pad 17 of the first wafer W1 and a first bonding pad 23a of the first core die 20a may make contact with each other. The front surface of the first core die 20a and a backside surface of the first wafer W1 may be bonded to face each other. When the first wafer W1 and the first core die 20a are bonded to each other by wafer-to-die bonding, the second bonding pad 17 of the first wafer W1 and the first bonding pads 23a of the first core die 20a may be bonded to each other by copper-copper hybrid bonding (Cu—Cu Hybrid Bonding).

As illustrated in FIGS. 14 and 15, processes the same as or similar to the processes described with reference to FIGS. 12 and 13 may be performed to attach a plurality of core dies 20b in a second stage on the plurality of first-stage core dies 20a on the first wafer W1 (die-to-wafer hybrid bonding process).

A front surface of the second-stage core die 20b may be stacked to face the backside surface of the first-stage core die 20a. By a thermal compression process, the second-stage core die 20b and the first-stage core die 20a may be bonded to each other through hybrid bonding. That is, a front insulating layer 22b on the front surface of the second-stage core die 20b may be directly bonded to a backside insulating layer 26a on the backside surface of the first-stage core die 20a. When the first-stage core die 20a and the second-stage core die 20b are bonded to each other by die-to-die bonding, a second bonding pad 27a of the first-stage core die 20a and a first bonding pad 23b of the second-stage core die 20b may be bonded to each other by copper-copper hybrid bonding.

As illustrated in FIG. 14, processes the same as or similar to the processes described with reference to FIGS. 12 and 13 may be performed to sequentially attach core dies 20c, 20d, 20e, 20f, 20g and 20h on the plurality of second-stage core dies 20b on the first wafer W1, to form the core die stack DS.

The core dies of the core die stack DS may have same first thicknesses T1. The first thickness T1 of each of the core dies may be within a range of about 20 μm to 100 μm. The core dies of the core die stack DS may have same first widths D1 (FIG. 1). The first width D1 of each of the core dies may be within a range of 3 mm to 30 mm.

Among the core dies of the core die stack DS, the uppermost core die 20h may include a substrate 21h and a front insulating layer 22h provided on a front surface of the substrate 21h and in which a first bonding pad 23h is provided. Unlike the other core dies 20a, . . . , 20g, a back insulating layer may not be provided on a second surface 214h, that is, an inactive surface, of the substrate 21h of the uppermost core die 20h. Additionally, the substrate 21h of the uppermost core die 20h may not be provided with through electrodes.

The uppermost core die 20h may have a thickness the same as those of the underlying core dies 20a, . . . , 20g. As the number of the stacked core dies increases, a cumulative amount of deformation occurring in the core dies increases, so that the backside surface 214h of the uppermost core die 20h has a curved surface shape.

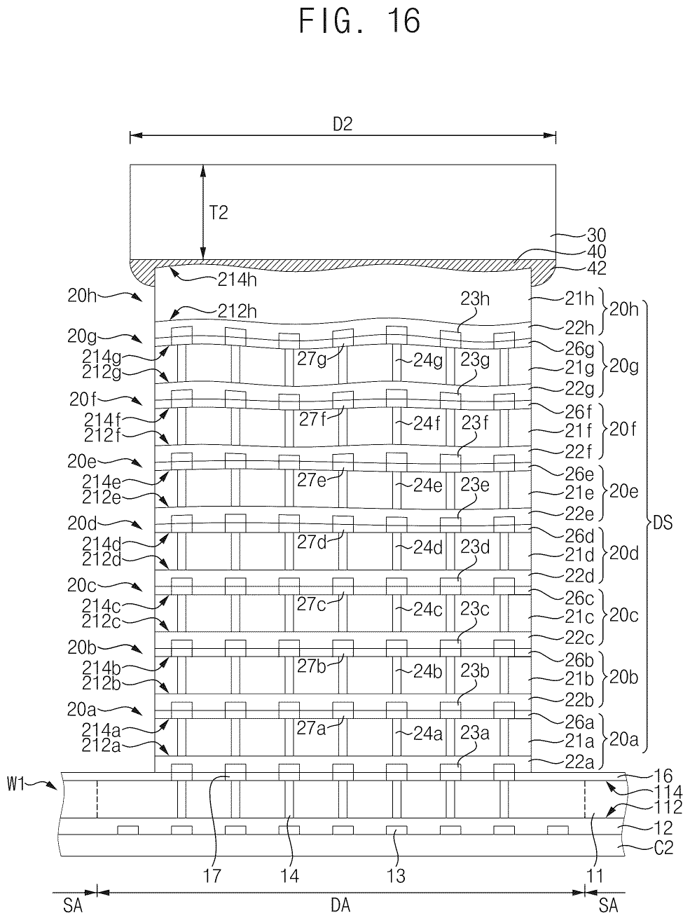

Referring to FIG. 16, a dummy support die 30 may be attached to the uppermost core die 20h of the core die stack DS using an adhesive member 40.

In example embodiments, a thermal conductivity of the dummy support die 30 may be greater than a thermal conductivity of each of the core dies. The dummy support die 30 may have a second thickness T2 greater than the first thickness T1 of the core die. The second thickness T2 of the dummy support die 30 may be within a range of 50 μm to 780 μm. The dummy support die 30 may have a second width D2 that is greater than the first width D1 of the core die. The dummy support die 30 may include an overhang portion OP protruding from an outer side surface of the uppermost core die 20h. A length L1 of the overhang portion OP protruding from the outer side surface SF of the uppermost core die 20h may be within a range of 30 μm to 300 μm.

The adhesive member 40 may include a non-conductive film (NCF). Alternatively, the adhesive member 40 may include epoxy, silicone, etc. A thickness of the adhesive member 40 may be within a range of 10 μm to 30 μm.

For example, the adhesive member 40 such as the non-conductive film may be attached on a silicon wafer, the silicon wafer may be diced to correspond to a shape of the uppermost core die 20h to form the dummy support die 30. Then, the dummy support die 30 may be attached to the backside surface 214h of the uppermost core die 20h by the adhesive member 40. Alternatively, after applying and curing a liquid epoxy material on a silicon wafer, the silicon wafer may be diced to correspond to the shape of the uppermost core die 20h to form the dummy support die 30.

Since the dummy support die 30 is attached by a thermal compression process, a portion of the adhesive member 40 between the uppermost core die 20h and the dummy support die 30 may be dispersed in an outward direction. Accordingly, the portion of the adhesive member 40 may extend downward from the overhang portion OP of the dummy support die 30 and may form a fillet portion 42 that covers at least a portion of an outer side surface of the uppermost core die 20h.

Since the uppermost core die 20h has the thickness the same as or similar to those of the other core dies 20a, . . . , 20g under the uppermost core die 20, the backside surface 214h of the uppermost core die 20h may have a curved surface depending on the accumulated amount of deformation occurring in the stacked core dies. By attaching the relatively thick dummy support die 30 using the adhesive member 40 on the curved surface of the uppermost core die, delamination or bubbles may be prevented from occurring at the bonding interface of the uppermost core die 20h, to thereby improve the bonding quality. Further, in a following molding process, the portion of the adhesive member 40 distributed and dispersed outside the uppermost core die 20h may be blocked by the overhang portion OP, and accordingly, a failure that the dispersed portion of the adhesive member 40 moves upward to protrude outward from an upper surface of a sealing member may be prevented.

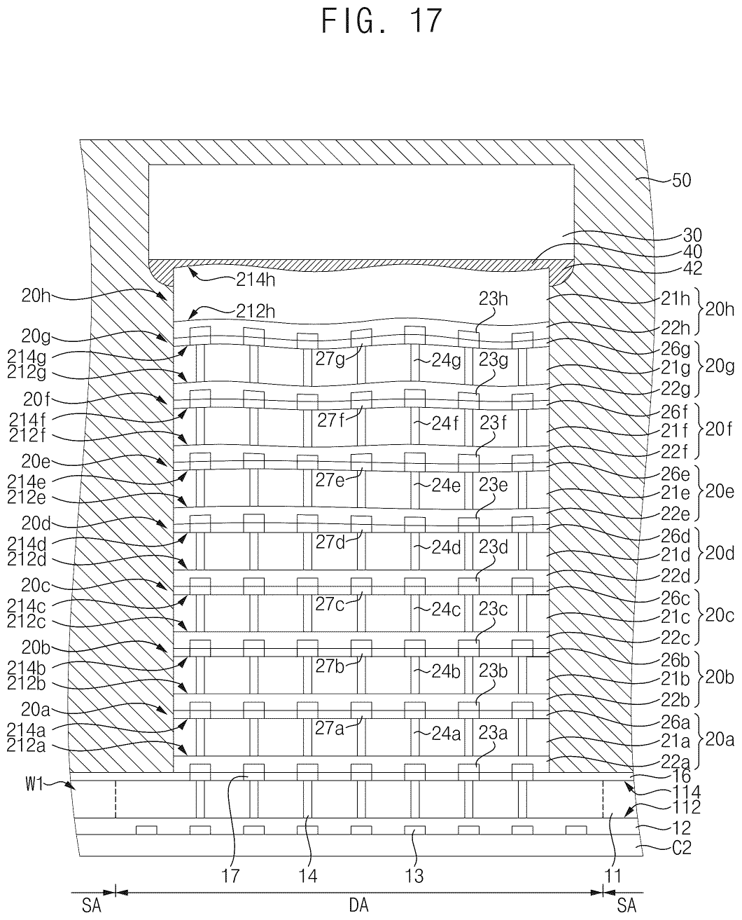

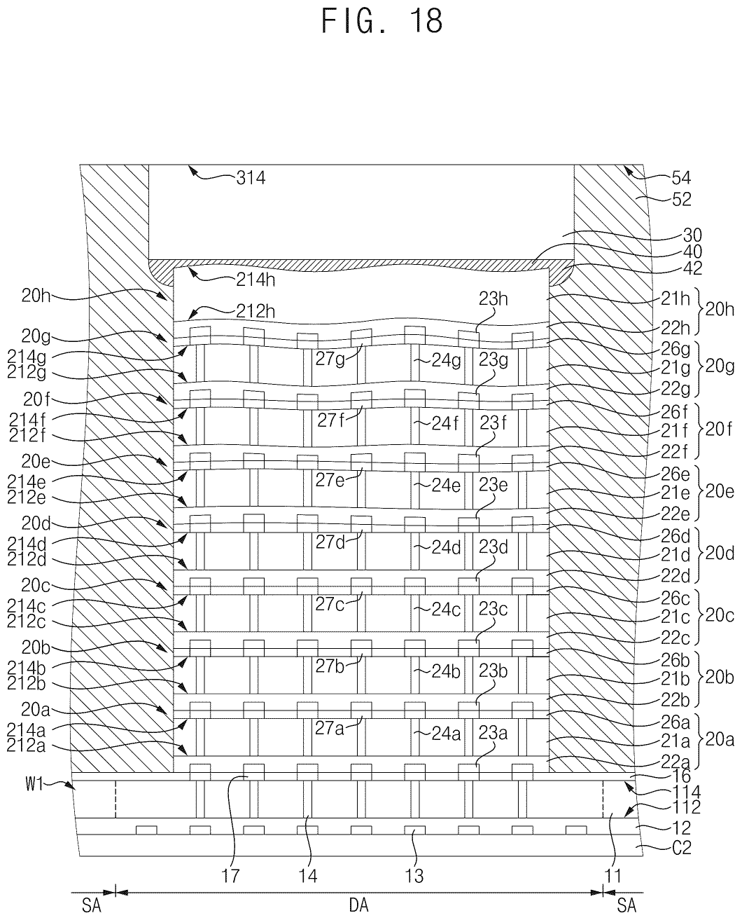

Referring to FIGS. 17 and 18, a sealing member 52 may be form on the first wafer W1 to cover an outer side surface of the core die stack DS and an outer side surface of the dummy support die 30.

As illustrated in FIG. 17, a sealant 50 may be formed on the first wafer W1 to cover the eight-stacked core dies 20a, 20b, 20c, 20d, 20e, 20f, 20g, 20h and the dummy support die 30. The sealant 50 may be formed through an over-molding process to cover an upper surface of the dummy support die 30.

For example, the sealant 50 may include epoxy molding compound (EMC), an inorganic dielectric layer, an organic dielectric layer, etc. The inorganic dielectric layer may include silicon oxide, silicon oxynitride, phosphosilicate glass (PSG), boro-phosphosilicate glass (BPSG), etc. The organic dielectric layer may include a polymer or the like.

As illustrated in FIG. 18, an upper portion of the sealant 50 may be removed to form a sealing member 52 that exposes the upper surface 314 of the dummy support die 30. The upper portion of the sealant may be removed by a chemical mechanical polishing process or a mechanical grinding process. In the grinding process, a portion of the adhesive member 40 distributed outside the bonding interface between the uppermost core die 20h and the dummy support die 30 may be blocked by the overhang portion OP, and accordingly, a failure that the dispersed portion of the adhesive member 40 moves upward to protrude outward from an upper surface of the sealing member 52 may be prevented.

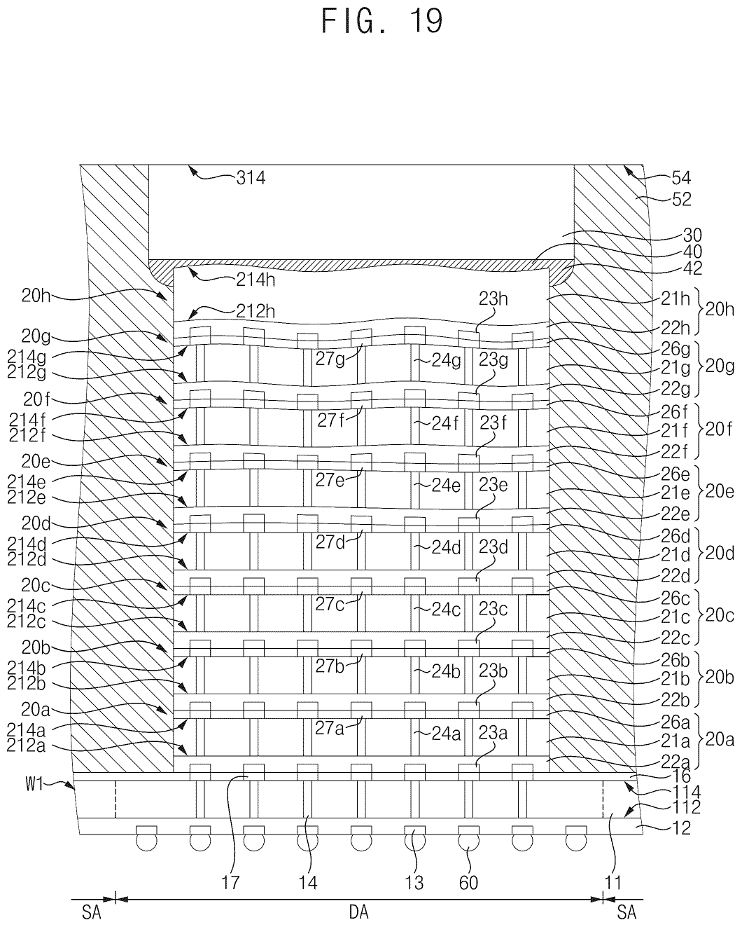

Referring to FIG. 19, conductive bumps 60 as conductive connection members may be formed on first bonding pads 13 of the first wafer W1.

For example, a seed layer may be formed on the first bonding pad 13 of the front insulating layer 12 of the first wafer W1, and a photoresist pattern having openings that expose portions of the seed layer may be formed on the seed layer on the front insulating layer 12. Then, the openings of the photoresist pattern may be filled up with a conductive material, the photoresist pattern may be removed and a reflow process may be performed to form solder bumps. For example, the conductive material may be formed on the seed layer by a plating process. Alternatively, the conductive bump may include a pillar bump and a solder bump formed on the pillar bump.

Then, the first wafer W1 and portions of the sealing member 52 may be cut along a scribe lane region SA to complete a semiconductor package 100 of FIG. 1.

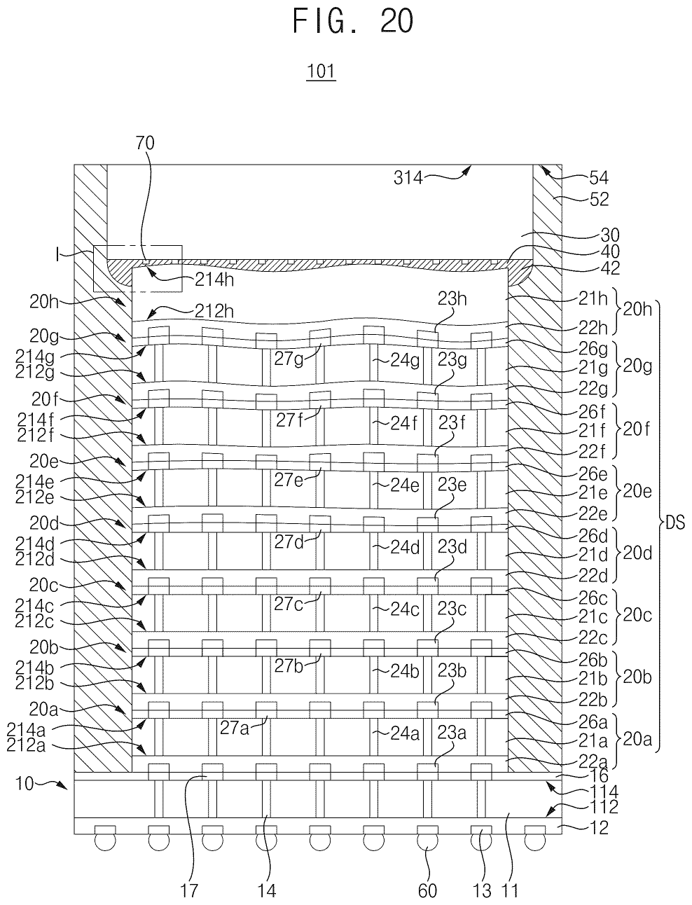

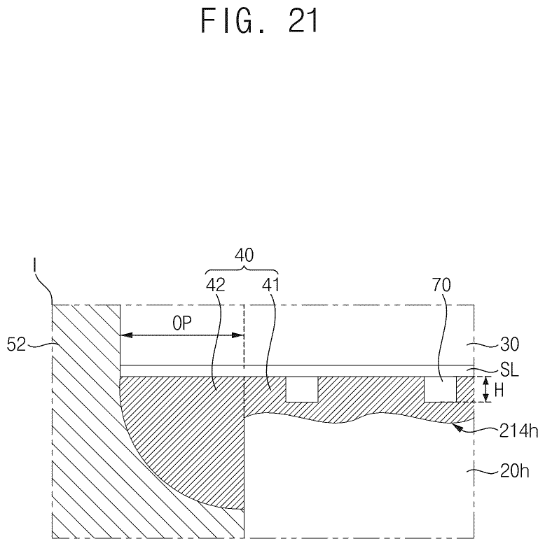

FIG. 20 is a cross-sectional view illustrating a semiconductor package in accordance with example embodiments. FIG. 21 is an enlarged cross-sectional view illustrating portion ‘I’ in FIG. 20. The semiconductor package is substantially the same as or similar to the semiconductor package described with reference to FIG. 1 except for additional heat dissipation bumps between a core die stack and a dummy support die. Thus, same reference numerals will be used to refer to the same or like elements and any further repetitive explanation concerning the above elements will be omitted.

Referring to FIGS. 20 and 21, a semiconductor package 101 may include a buffer die 10, a core die stack DS stacked on the buffer die 10, a dummy support die 30, an adhesive member 40, heat dissipation bumps 70 and a sealing member 52.

In example embodiments, the heat dissipation bumps 70 may be interposed between the uppermost core die 20h and the dummy support die 30. The heat dissipation bumps 70 may be formed on a first surface of the dummy support die 30. The adhesive member 40 may be attached on the first surface of the dummy support die 30 and may cover the heat dissipation bumps 70. A thickness of the adhesive member 40 may be greater than a height H of each of the heat dissipation bumps 70. The heat dissipation bumps 70 may have a cylindrical shape extending downward on the first surface of the dummy support die 30, as illustrated. Alternatively, the heat dissipation bumps 70 may have a polygonal pillar shape, such as a square pillar. The height H of each of the heat dissipation bumps 70 may be within a range of 1 μm to 30 μm. A thickness of the adhesive member 40 may be within a range of 10 μm to 30 μm.

For example, after a seed layer SL is formed on the first surface of the dummy support die 30, a photoresist pattern having openings that expose bump regions may be formed on the seed layer SL, and then, a plating process may be performed on the seed layer SL to form the heat dissipation bumps 70 on the first surface of the dummy support die 30. Then, the dummy support die 30 may be attached on a backside surface 214h of the uppermost core die 20h by the adhesive member 40.

Since the thickness of the adhesive member 40 is greater than the height H of each of the heat dissipation bumps 70, the heat dissipation bumps 70 may not contact the backside surface 214h of the uppermost core die 20h. The heat dissipation bumps 70 may have relatively high thermal conductivity. The heat dissipation bumps 70 may be interposed between the uppermost core die 20h and the dummy support die 30 and may efficiently transfer heat from the uppermost core die 20h to the dummy support die 30. Accordingly, the heat dissipation characteristics of the package may be improved.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a buffer die;
a plurality of core dies sequentially stacked on the buffer die;
a dummy support die attached to an uppermost core die among the plurality of core dies by an adhesive member; and
a sealing member on outer side surfaces of the plurality of core dies and on an outer side surface of the dummy support die,
wherein the dummy support die comprises an overhang portion that protrudes from the outer side surface of the uppermost core die, and
wherein the adhesive member comprises a fillet portion in contact with the overhang portion and that is on at least a portion of the outer side surface of the uppermost core die.

2. The semiconductor package of claim 1, wherein each of the plurality of core dies has a first thickness, and the dummy support die has a second thickness greater than the first thickness.

3. The semiconductor package of claim 2, wherein the first thickness is within a range of 20 μm to 100 μm, and the second thickness is within a range of 50 μm to 780 μm.

4. The semiconductor package of claim 1, wherein the adhesive member comprises a non-conductive film (NCF).

5. The semiconductor package according to claim 1, wherein a length of the overhang portion that protrudes from the outer side surface of the uppermost core die is within a range of 30 μm to 300 μm.

6. The semiconductor package according to claim 1, further comprising:
a plurality of heat dissipation bumps interposed between the uppermost core die and the dummy support die.

7. The semiconductor package of claim 1, wherein each of the plurality of core dies comprises:
a substrate;
a front insulating layer on a front surface of the substrate and comprising a first bonding pad; and
a backside insulating layer on a backside surface of the substrate and comprising a second bonding pad.

8. The semiconductor package of claim 7, wherein the backside insulating layer of a first core die among the plurality of core dies and the front insulating layer of a second core die stacked on the first core die are directly bonded to each other, and
the second bonding pad of the first core die and the first bonding pad of the second core die are directly bonded to each other.

9. The semiconductor package of claim 7, wherein the front insulating layer and the backside insulating layer comprise silicon oxide, silicon nitride, or silicon carbonitride.

10. The semiconductor package of claim 7, wherein each of the plurality of core dies further comprises a through electrode that penetrates the substrate and is electrically connected to the first and second bonding pads.

11. A semiconductor package, comprising:
a buffer die;
a plurality of core dies sequentially stacked on the buffer die, each of the plurality of core dies having a first width;
a dummy support die on an uppermost core die among the plurality of core dies, the dummy support die having a second width that is greater than the first width;
an adhesive member interposed between the uppermost core die and the dummy support die; and
a sealing member on outer side surfaces of the plurality of core dies and an outer side surface of the dummy support die,
wherein the adhesive member comprises a fillet portion on at least a portion of the outer side surface of the uppermost core die.

12. The semiconductor package of claim 11, wherein each of the plurality of core dies has a first thickness, and the dummy support die has a second thickness greater than the first thickness.

13. The semiconductor package of claim 12, wherein the first thickness is within a range of 20 μm to 100 μm, and the second thickness is within a range of 50 μm to 780 μm.

14. The semiconductor package of claim 11, wherein the dummy support die comprises a silicon die.

15. The semiconductor package of claim 11, wherein the adhesive member comprises a non-conductive film (NCF).

16. The semiconductor package of claim 11, wherein the fillet portion of the adhesive member extends outward from the outer side surface of the uppermost core die between 30 μm to 300 μm.

17. The semiconductor package of claim 11, wherein each of the plurality of core dies:
a substrate;
a front insulating layer on a front surface of the substrate and comprising a first bonding pad; and
a backside insulating layer on a backside surface of the substrate and comprising a second bonding pad.

18. The semiconductor package of claim 17, wherein the backside insulating layer of a first core die among the plurality of core dies and the front insulating layer of a second core die stacked on the first core die are directly bonded to each other, and
the second bonding pad of the first core die and the first bonding pad of the second core die are directly bonded to each other.

19. The semiconductor package of claim 17, wherein each of the plurality of core dies further comprises a through electrode that penetrates the substrate and is electrically connected to the first and second bonding pads.

20. A semiconductor package, comprising:
a buffer die;
a plurality of core dies sequentially stacked on the buffer die;
a dummy support die attached to an uppermost core die among the plurality of core dies by an adhesive member; and
a sealing member on outer side surfaces of the plurality of core dies and an outer side surface of the dummy support die,
wherein each of the plurality of core dies has a first thickness, and the dummy support die has a second thickness greater than the first thickness,
wherein each of the plurality of core dies has a first width, and the dummy support die has a second width greater than the first width, and
wherein the adhesive member comprises a fillet portion in contact with at least a portion of an outer side surface of the uppermost core die.
